(19) United States
(12) Patent Application Publication
(10) Pub. No.: US 2010/0227141 A1
(43) Pub. Date: Sep. 9, 2010

(54) PROTECTIVE COATING FOR INDUSTRIAL PARTS

(75) Inventor: Arianna T. Morales, Royal Oak, MI (US)

Correspondence Address: Julia Church Dierker;Dierker & Associates, P.C., 3331 W. Big Beaver Road, Suite 109, Troy, MI, 48084-2813, US

(73) Assignee: GM GLOBAL TECHNOLOGY OPERATIONS, INC., Detroit, MI (US)

(21) Appl. No.: 12/398,998

(22) Filed: Mar. 5, 2009

(51) Int. Cl. B32B 5/16; C23C 16/44; C23C 4/04; B05D 1/36; B05D 1/08

(52) U.S. Cl. 428/220; 428/323; 428/328; 428/327; 427/255.28; 427/248.1; 427/402; 427/446

(57) ABSTRACT

The instant disclosure relates to a protective coating for an industrial part working surface. The protective coating includes a first protective portion, and at least one additional protective portion positioned on the first protective portion. The first protective portion includes marker particles in a first coating matrix, where the marker particles make up from about 5 to 40 volume percent of the first protective portion and each marker particle has a diameter ranging from about 0.01 microns to 100 microns. The at least one additional protective portion includes a second coating matrix, and, in the second coating matrix, either i) a decreased amount of marker particles in comparison to an amount of the marker particles in the first protective portion or ii) no marker particles.

### TECHNICAL FIELD

The present disclosure relates generally to a protective coating for industrial parts.

### BACKGROUND

Currently, the working surfaces of industrial dies are often coated to increase their useful life. Such coated industrial dies are used in production operations until the coating established thereon fails, such as by breaking, delaminating or totally wearing off the underlying die in certain areas. In such instances, the dies have to be taken out of production for resurfacing and recoating of the working surfaces. This may be undesirable, at least in part because it may cause disruption of the production schedule, cost increases due to the reworking of the die working surfaces, and general loss in production time.

### SUMMARY

A protective coating for industrial parts is disclosed herein. The protective coating includes a first protective portion and at least one additional protective portion positioned on the first protective portion. The first protective portion includes marker particles in a first coating matrix. The marker particles make up from 5 to 40 volume percent of the first protective portion, and each marker particle has an average diameter ranging from 0.01 microns to 100 microns. The at least one additional protective portion includes a second coating matrix, and, in the second coating matrix, either i) a decreased amount of marker particles in comparison to an amount of the marker particles in the first protective portion or ii) no marker particles.

### BRIEF DESCRIPTION OF THE DRAWINGS

Features and advantages of embodiments of the present disclosure will become apparent by reference to the following detailed description and drawings, in which like reference numerals correspond to similar, though perhaps not identical, components. For the sake of brevity, reference numerals or features having a previously described function may or may not be described in connection with other drawings in which they appear.

FIGS. 1A and 1B are semi-schematic cross-sectional views illustrating embodiments of a protective coating on a work surface of an industrial part both before and after wear; and

FIGS. 2A, 2B and 2C are semi-schematic cross-sectional views illustrating three stages of wear of an embodiment of a protective coating on a work surface of an industrial part.

### DETAILED DESCRIPTION

The present disclosure relates generally to protective coatings for industrial parts, and various methods of making the same on such parts. In a non-limiting example, the industrial parts may be dies. Other non-limiting examples of such parts include general metal-forming tools, heaters, pre-heaters, presentation tables, and/or any metallic part in contact with forming sheet metal at any stage of the forming process. The protective coatings disclosed herein enable a user to determine, by simple visual examination of a color change on the coated surface of the industrial part surface, that the end of the useful life of the coated surface is approaching. This allows for the scheduling of recoating and/or resurfacing of industrial part surfaces before the current coating fails during operation. It is believed that such a warning system allows for better control of production scheduling and production times. By enabling the user to make the determination that the coating is near the end of its useful life, the use of the coated part can be stopped before damage to the part surface occurs. In some instances, this may reduce cost by eliminating the need for complete resurfacing of the tool.

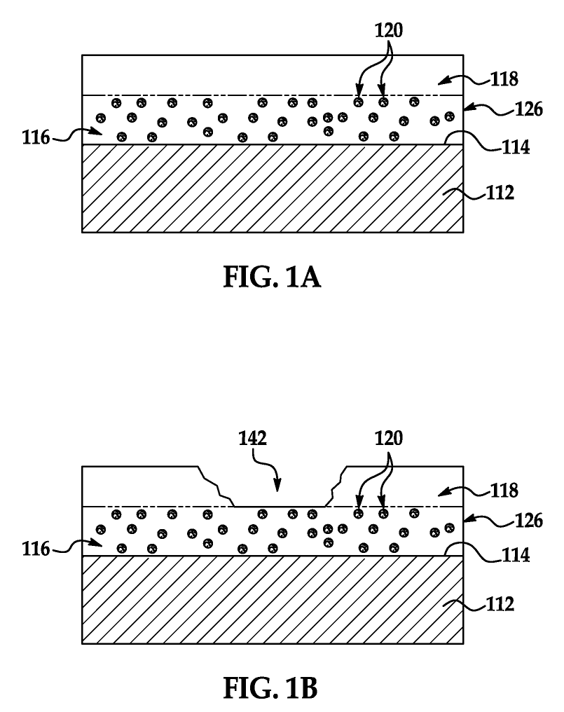

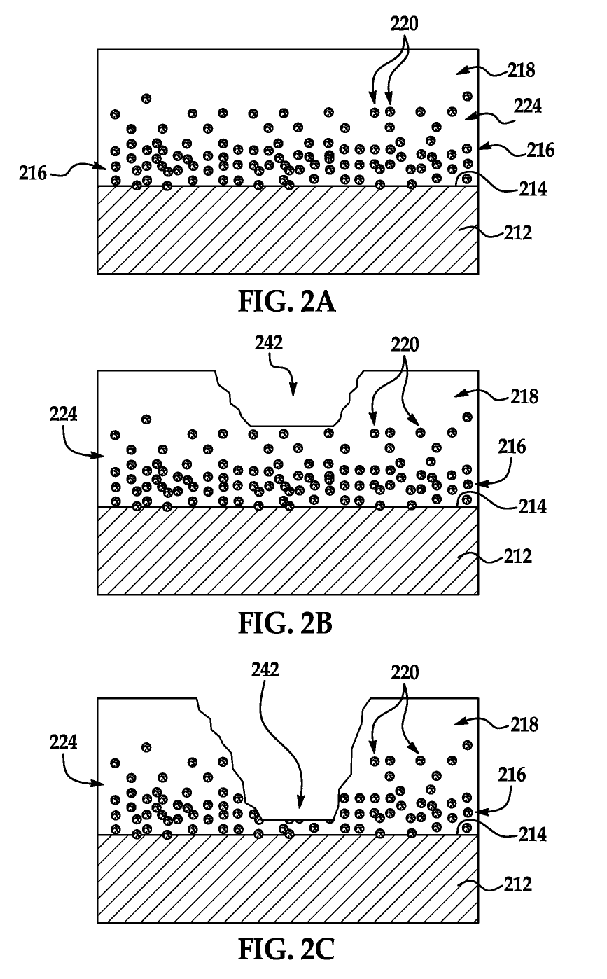

The protective coating disclosed herein may be made via multiple methods. Embodiments of the protective coating and its subsequent wear after use are shown in FIGS. 1A and 1B, and in FIGS. 2A, 2B and 2C.

FIG. 1A is a semi-schematic cross-sectional view of a working surface 114 of a die 112. The working surface 114 has been coated with the protective coating 126. The protective coating 126 includes a first protective portion (which, in some embodiments, is an inner layer) 116 having marker particles 120 therein, and at least one additional protective portion (which, in some embodiments, is an outer layer) 118 having few or no marker particles 120 therein.

The phantom line in FIG. 1A indicates i) that the coating 126 may be formed of a single composition in which the portions 116, 118 are formed when the marker particles 120 settle into the first protective portion 116, and ii) that the coating 126 may include two separate layers, each having its own composition. When the coating 126 includes two separate layers, the first/inner layer established on the surface 114 is the first protective portion 116, and the second/outer layer established on the first layer is the additional protective portion 118.

In a non-limiting embodiment, the coating matrix used in the coating composition (or, when separate layers are included, in the composition of each layer) may be one or more of the following: fluorocarbon polymers, gold, gold alloys, aluminum, silicon, carbon fiber, carbon nanofiber, carbon filament, carbon nanotube, silicon dioxide, silicon-germanium, tungsten, silicon carbide, silicon nitride, silicon oxynitride, titanium nitride, zirconium oxide, aluminum bronze, calcium zirconate, pure aluminum, cobalt-molybdenum, chromium cobalt, aluminum oxide, tungsten carbide, copper-aluminum alloys, copper-nickel alloys, copper-tin alloys, copper-zinc alloys, chromium carbide, nickel graphite, 316 stainless steel, fused nickel chromium, high carbon-iron-molybdenum composite, fused nickel-cobalt, fused tungsten carbide, white aluminum oxide, zinc, copper, aluminum oxide-titanium nickel aluminide, molybdenum, fused nickel-cobalt, nickel chromium, chromium oxide, titanium dioxide, stainless steel, low carbon steel, oxide coatings on steel, phosphate conversion, tin alloys, vitreous enamels, nickel alloys, aluminum-titanium dioxide, and tungsten. It is to be understood that in embodiments including separate layers, the coating matrix of each layer may be formed of the same material or different materials.

In another non-limiting embodiment, the marker particles 120 can include either a) particulates which change color upon exposure to air, the particulates including metals selected from the group consisting of magnesium, copper, zinc, aluminum, silica and combinations thereof; b) encapsulated metal particles selected from the group consisting of carboxy-functionalized silver, carboxy-functionalized titanium dioxide, amine-functionalized gold, carboxy-functionalized cerium (IV) oxide, carboxy-functionalized Fe₂O₃, carboxy-functionalized CdS-capped CdTe, carboxy-functionalized palladium, carboxy-functionalized zinc oxide and combinations thereof, c) encapsulated solid dye particles selected from the group consisting of fluorescent colored particles, carboxyl colored particles, carboxyl fluorescent colored particles, carboxyl-polystyrene colored particles, dimethylamino fluorescent particles, fluorescent carboxyl colored particles, fluorescent carboxyl colored particles, fluorescent polymethylmethacrylate colored particles, colored polystyrene particles; and combinations thereof. The marker particles 120 can also include a combination of any of a), b) and c) above.

It is to be understood that the previously listed materials may also be used in each of the other example embodiments disclosed herein and discussed hereinbelow.

FIG. 1B is a semi-schematic cross-sectional view of the die 112 of FIG. 1A after wear has occurred. After use, and as shown, the additional protective portion 118 has been worn through near its center to form an indentation 142 which extends down into the first protective portion 118. It is to be understood that the position of the indentation 142 is shown for illustrative purposes, and that wear may occur at any portion of the coating 126. In this embodiment, the first protective portion 116 has marker particles 120 dispersed substantially uniformly therein. As depicted in this embodiment, there is no gradation of the marker particles 120 throughout the coating 126. As such, the amount of particles 120 does not substantially increase or decrease if the indentation 142 were allowed to extend further into the first protective portion 118 toward the working surface 114 of the die 112. As such, once the wear of the coating 126 exposes the marker particles 120, color is revealed. At this point, a user of the die 112 would be warned that the die 112 should be resurfaced or recoated, as the color from the marker particles 120 is indicative of the wearing away of the coating 126.

FIG. 2A illustrates another example embodiment in which the coating 226 has a gradient formed therein. More specifically, FIG. 2A is a cross-sectional view of a working surface 214 of a die 212. The working surface 214 of the die 212 has been coated with another embodiment of the protective coating 226. The protective coating 226 includes the first protective portion 116 including a relatively large concentration of marker particles 220, a first additional protective portion 224 including a smaller concentration of marker particles 220 compared to the first protective portion 116, and a second additional protective portion 218 including no marker particles 220 or a smaller concentration of marker particles 220 compared to the first additional portion 224. In this embodiment, both the first protective portion 216 and the first additional protective portion 224 have marker materials 220 dispersed therein to form a gradient. The gradient has an increasing concentration of marker particles 220 starting from the first additional protective portion 224, which has a relatively small concentration of marker particles 220, and moving through the first protective portion 216, which has a larger concentration of marker particles 220, to the surface 214 of the die 212. The second additional portion 218 has little or no marker particles 220 therein. In the embodiment shown in FIG. 2, the coating 226 is made up of a single concentration which has the gradient formed therein.

In another embodiment, similar to that shown in FIG. 2A, the gradient is formed via three different layers. Together, these layers form the coating 226. The first of the layers corresponds to the first protective portion 116 and includes the highest concentration of marker particles 220 of the coating 226. The second of the layers corresponds to the first additional layer 224 and includes less marker particles 220 than the first layer. The third layer would include even less particles 220 (or no particles), thus corresponding to the second additional protective portion 218.

FIG. 2B is a semi-schematic cross-section view of the die 212 of FIG. 2A after some wear. The difference in the coating 226 after wear occurs is that at least some of the second additional portion 218 is worn through to form an indentation 242. When the wear on the coating 226 extends down into the first additional protective portion 224 just above the first protective portion 216, the color from the marker particles 220 in the first additional protective portion 224 appear. Since the concentration of particles 220 is not at the highest concentration within the portion 224, the color would not be as intense in the worn area of the coating 226 (represented by the indentation 242) as compared to the portion 216 having the highest concentration of particles 220. Thus, a user of the die 212 would be warned that the protective coating 226 of the die 212 is beginning to wear through. The less intense color would also indicate that the coating 226 may be exposed to additional wear before the die 212 needs to be resurfaced or recoated.

FIG. 2C is a semi-schematic cross-sectional view of the die 212 of FIGS. 2A and 2B after additional wear. After further use of the die 212, the indentation 242 becomes larger, and thus more of the coating 226 is removed. As more of the coating 226 is worn away, at least a portion of the first protective portion 216 (i.e., the innermost layer, closest to the work surface of the die 212) becomes exposed. Thus, since the indentation 242 exposes the first protective portion 216 and the relatively large concentration of marker particles 220 therein, the color from the newly exposed marker particles 220 is much more intense than the color exposed in the embodiment of FIG. 2B. Thus, a user of the die 212 would be warned that the protective coating 226 has nearly worn through to the working surface 214. The user would also know that the protective coating 226 needs to be resurfaced or recoated soon, and that it may be undesirable to use the die 212 again without such resurfacing or recoating.

The protective coating(s) 126, 226 disclosed herein used for surface modification and protection for an industrial part 112, 212 includes marking particles 120, 220 of nano or micro dimensions incorporated therein. Such particles 120, 220 enable the determination and warning of the end of the useful life of the treated working surface 114 (i.e., the coating 126, 226). The wear of the coating 126, 226 therefore warns of the need for resurfacing work before failure of the working surface 114. Such a warning system combined with an outer protective layer 118 (substantially without marking material 120, 220 therein) provides a way to assure proper servicing of industrial parts before catastrophic failures occur. It is believed that this system does not require specially trained personnel to make direct measurements on the working surface 114, 214 of the die 112, 212. Increased surface quality of the formed parts may be achieved, as well as a reduction in surface finishing costs.

In the embodiments disclosed herein, the marker particles 120, 220 constitute from 5 to 40 volume percent of the first protective portion/layer 116. Each marker particle 120, 220 has, in one embodiment, an average diameter ranging from 0.01 microns to 100 microns. It is to be understood that the additional protective portions/layers 118, 218, 224 formed on the first protective portion/layer 116 includes a decreased amount of the particles 120, 220 or none of the marker particles 120, 220 in a coating matrix.

An example of the method for forming an embodiment of the coating 126, 226 including separate layers is described herein. Different coating compositions are formed for each of the desirable layers. For each layer 116, 216, 224, 118, 218, the respective coating matrix is provided in a powder or liquid form. The desirable amount, if any, of the marker particles 120, 220 are added to the coating matrix. For example, the composition for the first layer 116, 216 will include the coating matrix and marker particles 120, 220 present in an amount ranging from 5 to 40 volume percent of the coating matrix. Similarly, the composition for the additional layer(s) 118, 224, 218 will include the coating matrix and less marker particles 120, 220 (than the layer 116, 216) or no marker particles 120, 220.

The next step is to apply the composition to form the first protective layer 116 to the industrial part working surface 114. The composition for the additional protective layer(s) 118, 224, 218 is then applied on the first protective layer 116, 216. As previously mentioned, the at least one additional protective layer 118, 224, 218 has either a lesser amount of the marker particles 120, 220 in comparison to the first protective layer 116, 216, or none of the marker particles 120, 220. The at least two protective layers 116, 216, 118, 218, 224 are applied to the industrial part working surface 114, 214 by one of several methods. These methods can be electroless metal plating, plating, physical vapor deposition, chemical vapor deposition, spraying, plasma spraying, burnishing, dripping, or combinations of any of the above.

In yet another embodiment, the method for forming the coating 126, 226 utilizes a single composition, as opposed to multiple separate layers. The method includes the following steps. Initially, a composition of the coating matrix (in a powder or liquid form) and marker particles 120 is generated. The next step is to apply the composition to the industrial part working surface 114, 214 to form the protective layer 126, 226. The marker particles 120, 220 in the protective layer 126, 226 sediment toward the region of the protective layer 126, 226 closest to the industrial part working surface 114, 214, thereby forming the first protective portion 116, 216 (i.e., the bottom half of the protective layer 126, 226). The settling of the particles 120, 220 causes a division within the protective layer 126, 226 to form the various portions 116, 216, 224, 118, 218. The protective layer 126, 226 is applied to the industrial part working surface 114, 214 by an applying method selected from the group consisting of electroless metal plating, plating, physical vapor deposition, chemical vapor deposition, spraying, plasma spraying, burnishing, dipping, and combinations thereof. In this example, the embodiment with the gradient may be formed by virtue of the fact that not all of the particles 120, 220 will settle into the same area of the coating.

In the embodiments disclosed herein, the total thickness of the protective coating 126, 226 on the industrial part work surface 114, 214 is from about 5 to 500 microns.

In one non-limiting example, the first protective layer 116, 216 includes from about 20 to 40 volume percent of the marker particles 120, 220, where the marker particles 120, 220 have an average diameter ranging from about 0.01 to 1 micron. In this non-limiting example, the total thickness of the coating 126, 226 ranges from about 5 to 50 microns.

In yet another non-limiting example, the first protective layer 116, 216 includes from about 5 to 20 volume percent of the marker particles 120, 220, where the marker particles 120, 220 have an average diameter ranging from about 1 to 100 microns. In this non-limiting example, the total thickness of the coating 126, 226 ranges from about 50 to 500 microns.

To further illustrate embodiment(s) of the instant disclosure, various examples are given herein. It is to be understood that these are provided for illustrative purposes and are not to be construed as limiting the scope of the disclosed embodiment(s). Where units are given as “parts” in the examples, they are all in weight parts, unless specified otherwise.

### EXAMPLES

### Example 1

A protective layer was applied to the work surface of a die. The protective layer components applied by electroless plating included nickel, polytetrafluoroethylene (PTFE), and polystyrene fluorescent particles. The coated die was used to form aluminum parts. The color of the polystyrene fluorescent particles was not visible until the time when the outermost layer on the die work surface had begun to wear away. This occurred after a certain number of parts were formed. With continued use of the coated die work surface, an obviously different color appeared on the surface of the coating. In the experiment, the thickness of the initial coating on the die, the number of parts formed up to when the change in color was detected, and the coating thickness on the die at the moment when color was detected, were correlated to determine the number of possible parts to be formed by the coated die before the coating wore off completely. The useful life of the die coating was thus detected.

### Example 2

A protective layer was applied to the work surface of a die. The protective layer components applied by plasma spray included CrC/NiCr and silica particles. The resulting protective layer's silica particles were not visible until after the protective layer on the die work surface had begun to wear away. With continued use of the die work surface, an obviously different color appeared on the work away surface of the protective layer.

While several examples have been described in detail, it will be apparent to those skilled in the art that the disclosed examples may be modified. Therefore, the foregoing description is to be considered exemplary rather than limiting.

1. A protective coating for an industrial part working surface, the protective coating comprising:
a first protective portion including marker particles in a first coating matrix, the marker particles making up from about 5 to 40 volume percent of the first protective portion and each marker particle having an average diameter ranging from about 0.01 microns to 100 microns; and
at least one additional protective portion positioned on the first protective portion, the at least one additional protective portion including a second coating matrix, and either i) a decreased amount of marker particles in comparison to an amount of the marker particles in the first protective portion or ii) no marker particles in the second coating matrix.

2. The protective coating of claim 1 wherein the first protective portion is a first layer of the coating, and wherein the at least one additional protective portion is a second layer of the coating that is separate from the first layer.

3. The protective coating of claim 1 wherein the first protective portion and the at least one additional protective portion are part of a single composition in which the first and second coating matrices are the same and at least a majority of the marker particles settle into the first protective portion.

4. The protective coating of claim 1 wherein the coating matrices are selected from the group consisting of fluorocarbon polymers, gold, gold alloys, aluminum, silicon, carbon fiber, carbon nanofibers, carbon filaments, carbon nanotubes, silicon dioxide, silicon-germanium, tungsten, silicon carbide, silicon nitride, silicon oxynitride, titanium nitride, zirconium oxide, aluminum bronze, calcium zirconate, pure aluminum, cobalt-molybdenum, chromium cobalt, aluminum oxide, tungsten carbide, copper-aluminum alloys, copper-nickel alloys, copper-tin alloys, copper-zinc alloys, chromium carbide, nickel graphite, 316 stainless steel, fused nickel chromium, high carbon-iron-molybdenum composite, fused nickel-cobalt, fused tungsten carbide, white aluminum oxide, zinc, copper, aluminum oxide-titanium nickel aluminide, molybdenum, fused nickel-cobalt, nickel chromium, chromium oxide, titanium dioxide, stainless steel, low carbon steel, phosphate conversion, tin alloys, vitreous enamels, nickel alloys, aluminum-titanium dioxide, and tungsten, and combinations thereof.

5. The protective coating of claim 1 wherein the marker particles include either a) particulates which change color upon exposure to air, the particulates including metals selected from the group consisting of magnesium, copper, zinc, aluminum, silica, and combinations thereof, or b) encapsulated metal particles selected from the group consisting of carboxy-functionalized silver, carboxy-functionalized titanium dioxide, amine-functionalized gold, carboxy-functionalized cerium (IV) oxide, carboxy-functionalized Fe₂O₃, carboxy-functionalized CdS-capped CdTe, carboxy-functionalized palladium, carboxy-functionalized zinc oxide, and combinations thereof, or c) encapsulated solid dye particles selected from the group consisting of fluorescent colored particles, carboxyl colored particles, carboxyl fluorescent colored particles, carboxyl-polystyrene colored particles, dimethylamino fluorescent particles, fluorescent carboxyl colored particles, fluorescent carboxyl colored particles, fluorescent polymethylmethacrylate colored particles, colored polystyrene particles, and combinations thereof; or d) combinations of at least two of a), b), and c).

6. The protective coating of claim 1 wherein a total thickness of the coating ranges from about 5 to 500 microns.

7. The protective coating of claim 1 wherein the first protective portion includes from about 20 to 40 volume percent of the marker particles, wherein each of the marker particles has an average diameter ranging from about 0.01 to 1 micron; and wherein a total thickness of the coating ranges from about 5 to 50 microns.

8. The protective coating of claim 1 wherein the at least one additional protective portion includes at least two additional protective portions, wherein a first of the at least two additional protective portions includes a concentration of marker particles less than a concentration in the first protective portion and a second of the at least two additional protective portions includes a concentration of marker particles less than the concentration in the first of the at least two additional protective portions, and wherein the protective coating thus includes a gradient of increasing concentration of marker particles in a direction toward the industrial part working surface.

9. The protective coating of claim 1 wherein the first protective portion includes from 5 to 20 volume percent of the marker particles, wherein each of the marker particles has an average diameter ranging from about 1 to 100 microns, and wherein a total thickness of the coating ranges from about 50 to 500 microns.

10. A method of making a protective coating on an industrial part working surface, the method comprising:
applying a first protective layer to the industrial part working surface, the first protective layer including:
a coating matrix; and
marker particles mixed in the coating matrix, the marker particles having an average diameter ranging from 0.01 microns to 100 microns, and being present in the coating matrix in an amount ranging from 5 to 40 volume percent of a total volume of the first protective layer; and
applying at least one additional protective layer on the first protective layer, the at least one additional protective layer including:
a same coating matrix as the coating matrix of the first protective layer; and
either i) a decreased amount of marker particles in comparison to an amount of the marker particles in the first protective layer or ii) no marker particles;
wherein the at least two protective layers are applied to the industrial part working surface by an applying method selected from the group consisting of electroless metal plating, physical vapor deposition, chemical vapor deposition, plasma spray, and combinations thereof.

11. The method of claim 10 wherein the coating matrices are selected from the group consisting of fluorocarbon polymers, gold, gold alloys, aluminum, silicon, carbon fiber, carbon nanofibers, carbon filaments, carbon nanotubes, silicon dioxide, silicon-germanium, tungsten, silicon carbide, silicon nitride, silicon oxynitride, titanium nitride, zirconium oxide, aluminum bronze, calcium zirconate, pure aluminum, cobalt-molybdenum, chromium cobalt, aluminum oxide, tungsten carbide, copper-aluminum alloys, copper-nickel alloys, copper-tin alloys, copper-zinc alloys, chromium carbide, nickel graphite, 316 stainless steel, fused nickel chromium, high carbon-iron-molybdenum composite, fused nickel-cobalt, fused tungsten carbide, white aluminum oxide, zinc, copper, aluminum oxide-titanium nickel aluminide, molybdenum, fused nickel-cobalt, nickel chromium, chromium oxide, titanium dioxide, stainless steel, low carbon steel, oxide coatings on steel, phosphate conversion, tin alloys, vitreous enamels, nickel alloys, aluminum-titanium dioxide, and tungsten, and combinations thereof.

12. The method of claim 10 wherein the marker particles include either a) particulates which change color upon exposure to air, the particulates including metals selected from the group consisting of magnesium, copper, zinc, aluminum, silica, and combinations thereof, or b) encapsulated metal particles selected from the group consisting of carboxy-functionalized silver; carboxy-functionalized titanium dioxide; amine-functionalized gold; carboxy-functionalized cerium (IV) oxide; carboxy-functionalized Fe₂O₃; carboxy-functionalized CdS-capped CdTe; carboxy-functionalized palladium; carboxy-functionalized zinc oxide and combinations thereof, or c) encapsulated solid dye particles selected from the group consisting of fluorescent colored particles, carboxyl colored particles, carboxyl fluorescent colored particles, carboxyl-polystyrene colored particles, dimethylamino fluorescent particles, fluorescent carboxyl colored particles, fluorescent carboxyl colored particles, fluorescent polymethylmethacrylate colored particles, colored polystyrene particles, and combinations thereof, or d) combinations of at least two of a), b) and c).

13. The method of claim 10 wherein the first protective layer and the at least one additional protective layer are applied with physical vapor deposition or chemical vapor deposition, wherein the marker particles make up from 20 to 40 volume percent of the first protective layer, wherein each of the marker particles has a diameter ranging from 0.01 to 1 micron, and wherein a total thickness of the coating ranges from 5 to 50 microns.

14. The method of claim 10 wherein the first protective layer is applied with plasma spray, wherein the marker particles make up from 5 to 20 volume percent of the first protective layer, wherein each of the marker particles has a diameter ranging from 1 to 100 microns, and wherein a total thickness of the coating ranges from 50 to 500 microns.

15. The method of claim 10 wherein the at least one additional protective layer includes at least two additional protective layers, and wherein the method further comprises:
applying a first of the at least two additional protective layers on the first protective layer, the first of the at least two additional protective layers including a concentration of marker particles that is less than a concentration in the first protective layer; and
applying a second of the at least two additional protective layers on the first of the at least two additional protective layers, the second of the at least two additional protective layers including a concentration of marker particles that is less than the concentration in the first of the at least two additional protective layers, thereby creating a gradient of increasing concentration of marker particles in a direction toward the industrial part working surface.

16. A method of making a protective coating on an industrial part working surface, the method comprising:
preparing a composition of a coating matrix in a powder or liquid form with marker particles therein, the marker particles making up from 5 to 40 volume percent of the mixture, and having an average diameter ranging from 0.01 microns to 100 microns; and
applying the composition to the industrial part working surface, thereby forming the protective coating, whereby the marker particles sediment toward a first protective portion of the protective coating that is adjacent to the industrial part working surface, thus causing a second protective portion to form which includes either i) a decreased amount of marker particles in comparison to an amount of the marker particles in the first protective portion or ii) no marker particles;
wherein the protective coating is applied to the industrial part working surface via an applying method selected from the group consisting of electroless metal plating, plating physical vapor deposition, chemical vapor deposition, spraying, plasma spraying, burnishing, dipping and combinations thereof.

17. The method of claim 16 wherein the coating matrix is selected from the group consisting of fluorocarbon polymers, gold, gold alloys, aluminum, silicon, carbon fiber, carbon nanofibers, carbon filaments, carbon nanotubes, silicon dioxide, silicon-germanium, tungsten, silicon carbide, silicon nitride, silicon oxynitride, titanium nitride, zirconium oxide, aluminum bronze, calcium zirconate, pure aluminum, cobalt-molybdenum, chromium cobalt, aluminum oxide, tungsten carbide, copper-aluminum alloys, copper-nickel alloys, copper-tin alloys, copper-zinc alloys, chromium carbide, nickel graphite, 316 stainless steel, fused nickel chromium, high carbon-iron-molybdenum composites, fused nickel-cobalt, fused tungsten carbide, white aluminum oxide, zinc, copper, aluminum oxide-titanium nickel aluminide, molybdenum, fused nickel-cobalt, nickel chromium, chromium oxide, titanium dioxide, stainless steel, low carbon steel, oxide coatings on steel, phosphate conversion, tin alloys, vitreous enamels, nickel alloys, aluminum-titanium dioxide, and tungsten, and combinations thereof.

18. The method of claim 16 wherein the marker particles include either a) particulates which change color upon exposure to air, the particulates including metals selected from the group consisting of magnesium, copper, zinc, aluminum, silica, and combinations thereof; or b) encapsulated metal particles selected from the group consisting of carboxy-functionalized silver; carboxy-functionalized titanium dioxide; amine-functionalized gold; carboxy-functionalized cerium (IV) oxide; carboxy-functionalized Fe₂O₃; carboxy-functionalized CdS-capped CdTe; carboxy-functionalized palladium; carboxy-functionalized zinc oxide and combinations thereof; or c) encapsulated solid dye particles selected from the group consisting of fluorescent colored particles, carboxyl colored particles, carboxyl fluorescent colored particles, carboxyl-polystyrene colored particles, dimethylamino fluorescent particles, fluorescent carboxyl colored particles, fluorescent carboxyl colored particles, fluorescent polymethylmethacrylate colored particles, colored polystyrene particles, and combinations thereof, or d) combinations of at least two of a), b) and c).

19. The method of claim 16 wherein the composition is applied with physical vapor deposition or chemical vapor deposition, wherein the marker particles make up from 20 to 40 volume percent of the first protective portion, wherein each of the marker particles has a diameter ranging from 0.01 to 1 micron, and wherein a total thickness of the coating ranges from 5 to 50 microns.

20. The method of claim 16 wherein the composition is applied with plasma spray, wherein the marker particles make up from 5 to 20 volume percent of the first protective portion, wherein each of the marker particles has a diameter ranging from 1 to 100 microns, and wherein a total thickness of the coating ranges from 50 to 500 microns.

21. The method of claim 16 wherein the marker particles sediment to form throughout the coating matrix a gradient of increasing concentration of marker particles in a direction toward the industrial part working surface.
